(19) United States
(12) Patent Application Publication
(10) Pub. No.: US 2026/0251709 A1
(43) Pub. Date: Aug. 27, 2026

(54) SELF-TEST SYSTEM FOR APPLICATION-SPECIFIC INTEGRATED CIRCUIT (ASIC) DEVICES

(71) Applicant: Micron Technology, Inc., Boise, ID (US)

(72) Inventors: Banadappa Veerabhadrappa Shivaray, Gulbarga (IN); Pranjal Chauhan, Allen, TX (US); Srinivasa Rao Jaladi, Bangalore (IN); Jayaprakash Naradasi, Karnataka (IN); Mahesh Rawal, Hyderabad (IN); Naveen Kodumuri, Hyderabad (IN)

(21) Appl. No.: 19/548,374

(22) Filed: Feb. 24, 2026

Related U.S. Application Data
(60) Provisional application No. 63/762,953, filed on Feb. 25, 2025.

(51) Int. Cl. G01R 31/3177; G01R 31/317

(52) U.S. Cl. CPC G01R 31/3177; G01R 31/31724; G01R 31/31727

(57) ABSTRACT

A memory device comprises a storage component for Logic Built-In Self-Test (LBIST) pattern seed information and an In-System Test (IST) controller. The IST controller receives a host command to initiate self-test, loads pattern seed information, triggers test execution, and provides status information to the host. The storage component may be random access memory, allowing dynamic modification of test patterns. This on-demand LBIST architecture enables fault detection during device operation and allows flexible test pattern generation that can adapt to changing requirements.

### PRIORITY APPLICATION

This application claims the benefit of priority to U.S. Provisional Application Ser. No. 63/762,953, filed Feb. 25, 2025, which is incorporated herein by reference in its entirety.

### TECHNICAL FIELD

The present disclosure relates to Application-Specific Integrated Circuit (ASIC) devices and self-test systems and methods for such devices.

### BACKGROUND

Memory devices are components in various electronic systems, storing and retrieving information critical for their operation. As these devices become more complex and are integrated into safety-critical applications, ensuring their reliability and fault tolerance becomes increasingly important. In-System Test (IST) and Logic Built-In Self-Test (LBIST) are techniques used to verify the functionality of memory devices and detect potential faults.

Some IST and LBIST implementations use fixed test patterns stored in read-only memory (ROM) to verify the functionality of logic gates, flip-flops, or other components associated with memory devices. Some LBIST approaches may incorporate pseudo-random pattern generators and signature analysis techniques to detect faults in the logic circuitry associated with memory devices.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example of an In-System Test (IST) controller with a Test Access Port (TAP) interface according to some examples described herein.

FIG. 2 illustrates generally an example of In-System Test architecture with on-demand features according to some examples described herein.

FIG. 3 illustrates generally an example of a diagram illustrating an IST controller interface.

FIG. 4 illustrates generally an example of a memory device with on-demand Logic Built-In-Self-Test (LBIST) capabilities according to some examples described herein.

FIG. 5 illustrates generally an example method for performing on-demand Logic Built-In-Self-Test (LBIST) in a memory device in accordance with some examples described herein.

FIG. 6 illustrates generally an example of a block diagram of a machine upon which or with which one or more examples described herein may be implemented.

### DETAILED DESCRIPTION

Memory devices are essential components in various electronic systems. Memory devices store and retrieve information critical for the operation of electronic devices and systems. As these devices become more complex and are integrated into safety-critical applications (such as vehicles and medical devices), ensuring their reliability and fault tolerance becomes increasingly important. In-System Test (IST) and Logic Built-In Self-Test (LBIST) are techniques used to verify the functionality of memory devices and detect potential faults. These testing methodologies have evolved to address the growing demands of modern memory systems, particularly in applications where continuous monitoring of device health is crucial.

Some IST and LBIST implementations rely on read-only memory (ROM) to store test patterns and are typically executed only during power-on or power-off sequences. For example, these implementations may use fixed test patterns stored in ROM, which can be used to verify the functionality of memory cells, access lines, and other critical components of the memory device. Additionally, some LBIST approaches may incorporate pseudo-random pattern generators and signature analysis techniques to detect faults in the logic circuitry associated with memory devices. These approaches can limit the flexibility of the test process and do not adequately address the need for continuous fault detection during the operational lifetime of the device. Additionally, as memory devices scale to higher densities and more complex architectures, the physical area available for test circuitry becomes a consideration. Some IST or LBIST solutions use ROM to store seed values or Multiple Input Signature Register (MISR) values and are executed only during power-on or power-off sequences. In an example, these implementations may use fixed values stored in ROM to verify the functionality of logic gates, flip-flops, or other components of a memory device. This approach can limit the flexibility of the test process and does not adequately address the need for continuous fault detection during the operational lifetime of the device.

The present disclosure relates to an on-demand Direct Memory Access (DMA) based LBIST architecture and methodology for memory devices. In an example, the systems and methods discussed herein can address limitations of some existing LBIST implementations by allowing for greater flexibility in test pattern generation and execution, and enabling on-demand testing during functional operation of a memory device. In some examples, an LBIST system uses random access memory (RAM) or other memory, such as instead of ROM, to store LBIST pattern seed information. This approach allows for dynamic modification of test patterns, and enables the system to adapt to new or updated safety standards (e.g., as defined by Automotive Safety Integrity Level (ASIL) requirements, among others) without hardware changes. In an example, the test system or test procedure can be triggered on-demand by a host device, allowing for more frequent testing and earlier detection of potential faults.

The architecture examples disclosed herein include components such as an In-System Test (IST) controller, a DMA-based test controller, and an on-chip clock controller (OCC), among others. These components work together to manage the LBIST process, control clock domains during testing, and ensure smooth integration with the device's normal operation.

The systems and methods discussed herein can be used to meet various safety standards, such as Automotive Safety Integrity Level (ASIL) standards, by adjusting the pattern count needed to meet coverage requirements. This flexibility allows the same hardware architecture to be used across different applications with varying safety requirements. Additionally, the ability to run LBIST during functional operation addresses the need for continuous fault detection in mission-critical applications. The on-demand nature of the LBIST system allows for testing to be performed at any point during the device's operation, not just during power-on or power-off sequences. This capability is particularly beneficial for automotive applications, where latent faults need to be detected and addressed promptly to maintain system safety and reliability.

Implementation of the LBIST system architecture involves modifications to existing memory device designs, including integration of an IST controller, a DMA-based test controller, and associated circuitry. The system is designed to have minimal impact on the memory device's power consumption and functionality during LBIST execution, making it suitable for use in power-sensitive applications.

The disclosed on-demand DMA-based LBIST architecture and methodology offer several potential advantages over existing techniques, including increased flexibility, on-demand testing, improved fault coverage, compatibility with multiple standards, reduced boot time or device startup overhead, enhanced safety, minimal impact on normal device function, and a simplified design process. For example, use of RAM instead of ROM for storing test patterns allows for dynamic modification of test sequences, enabling adaptation to different testing requirements or standards without hardware changes. An ability to initiate LBIST at any time during device operation, rather than only during power cycles, allows for more frequent and timely fault detection. By allowing for adjustable pattern counts and test sequences, the system can potentially achieve higher fault coverage rates, enhancing overall device reliability. The architecture's flexibility enables it to meet various safety requirements (e.g., ASIL requirements) using the same hardware, potentially reducing design and manufacturing costs. Since LBIST can be performed on-demand rather than at every power-on, the system can potentially reduce boot time in applications where rapid startup is important or critical. For instance, in a car's infotainment system or engine control unit, rapid startup is often crucial for user experience or safety reasons. Additionally, an ability to perform frequent, on-demand testing is particularly beneficial for automotive and medical equipment, where continuous monitoring of device health is crucial. For example, in an automotive infotainment system, LBIST can run during vehicle startup to ensure system integrity before the driver relies on navigation or communication features. In an engine control unit, periodic LBIST execution could help detect potential faults before they lead to engine malfunction or failure.

In an example, the system is designed to have low power consumption and minimal interference with the device's functional operation during LBIST execution. For instance, in a memory controller for a solid-state drive, the LBIST process can be scheduled during periods of low activity, ensuring that read and write operations are not significantly impacted. The use of safe mode and careful clock management helps maintain system stability during testing. In an example, using a single hardware implementation for various ASIL standards can streamline the design and verification process for memory devices used in safety-critical applications.

In summary, the on-demand DMA-based LBIST system architecture and methodology presented herein improve flexibility, fault detection capabilities, and overall system reliability for memory devices. By providing a more adaptable and efficient testing framework, this approach addresses the growing need for robust fault detection in memory devices used in safety-critical applications, particularly in the automotive and medical fields.

While the discussion herein is, in some examples, in the context of Logic Built-In Self-Test (LBIST), the programmable random-access memory (RAM)-based architecture discussed herein can be applied to any test involving the programming of Test Data Registers (TDRs). For example, the architecture may be used with Memory Built-In Self-Test (MBIST) for testing memory cells and access lines, Embedded Deterministic Test (EDT) for scan-based testing, or other tests. The DMA-based approach using RAM instead of ROM enables flexible programming of test patterns, configuration data, and control values for various types of testing including stuck-at fault testing and at-speed testing across LBIST, MBIST, and scan-based test implementations. This programmable architecture allows for dynamic modification of test parameters and coverage requirements across different test methodologies while maintaining the advantages of on-demand testing during functional operation.

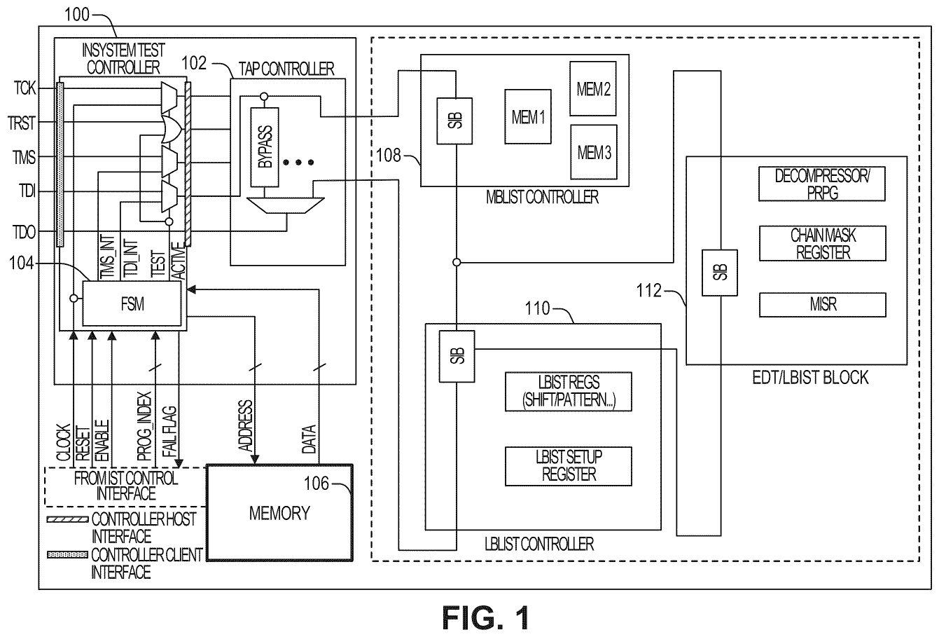

FIG. 1 illustrates an example of a portion of a memory device that includes an In-System Test controller (IST controller 100) with a Test Access Port (TAP) interface according to some examples described herein. The IST controller 100 may include various components and interfaces to facilitate on-chip testing of memory devices. For example, The IST controller 100 may be coupled to a TAP controller 102. The TAP controller 102 may be configured to manage the communication between the IST controller 100 and external test equipment (e.g., automated test equipment systems, JTAG boundary scan testers, logic analyzers, In-circuit emulators, field-programable gate array based testers, or the like) or other on-chip components. The TAP controller 102 may receive an input signal such as a test clock (tck), a test reset (trst), or a test mode select (tms), and may output a test data output (tdo) signal.

A finite state machine (FSM 104) may be included within the IST controller 100. The FSM 104 may control the overall operation of the IST controller 100, managing the flow of test data and control signals. The FSM 104 may receive inputs such as clock, reset, and enable signals, and may generate control signals for other components within the IST controller 100.

The IST controller 100 may interface with a memory component 106. The memory component 106 may store test patterns, configuration data, or other information required for the In-System Test operations. In some examples, the memory component 106 may be a read-only memory (ROM). However, in the on-demand Direct Memory Access (DMA) based Logic Built-In Self-Test (LBIST) architecture, this memory component 106 may be replaced with a random access memory (RAM) to allow for greater flexibility in test pattern generation and execution.

The IST controller 100 may also interface with various test-related components, such as a Memory Built-In Self-Test controller (MBIST controller 108), an LBIST controller 110, and an Enhanced Deterministic Test and Logic Built-in Self-test block (EDT/LBIST block 112). These components may work together to perform comprehensive testing of the memory device. The MBIST controller 108 may be responsible for or configured for testing memory-specific functions, such as read/write operations, addressing, and data integrity. The MBIST controller 108 may include multiple memory interfaces (MEM 1, MEM 2, MEM 3) to test different memory blocks or types within the device.

The LBIST controller 110 may manage the Logic Built-In Self-Test operations. It may include components such as LBIST registers for storing test patterns and configuration data, and a BIST setup register for controlling the LBIST operation parameters. The EDT/LBIST block 112 may contain additional components for enhancing the LBIST functionality. These may include a decompressor/pseudo-random pattern generator (PRPG) for generating test patterns, a chain mask register for selectively enabling or disabling certain test chains, and a multiple input signature register (MISR) for compacting test responses into a signature for analysis. The IST controller 100 may communicate the various components through a network of Segment Insertion Bit (SIB) interfaces, allowing for flexible and scalable test configurations. This architecture enables the IST controller 100 to manage and coordinate various test operations across different parts of the memory device.

The LBIST controller 110 may include other components for managing test operations. For example, the LBIST controller may include or use a phase-locked loop (PLL) and clock controller for managing test clock signals, counters for tracking test progress, and scan chain components for test pattern applications. The EDT/LBIST block 112 may include a decompressor/pseudo-random pattern generator (PRPG) for generating test patterns. In an example, the EDT/LBIST block 112 can receive shift clock and capture enable signals to control its operation. A compactor may be included to compress test responses from the circuit under test. A chain mask register may allow for selective enabling or disabling of scan chains during testing. A multiple input signature register (MISR) may be enabled by control signals to generate signatures based on compacted test responses.

In some examples, the IST controller 100 may be connected directly to an Internal Joint Test Action Group (IJTAG) scan interface. This connection may use an 8-pin IJTAG interface with signals for clock, reset, select, shift/capture/update, scan in, and scan out. This IJTAG interface may provide alternative access to the IST controller 100 and its associated test components. In an example, the LBIST architecture can be implemented as a hard macro block or a stand-alone physical block or component. When implemented as a hard macro block, the architecture may include dedicated clock domains, including system clock, BIST clock, and EDT clock domains, such as to allow for proper synchronization and control of the LBIST process across different parts of the circuit.

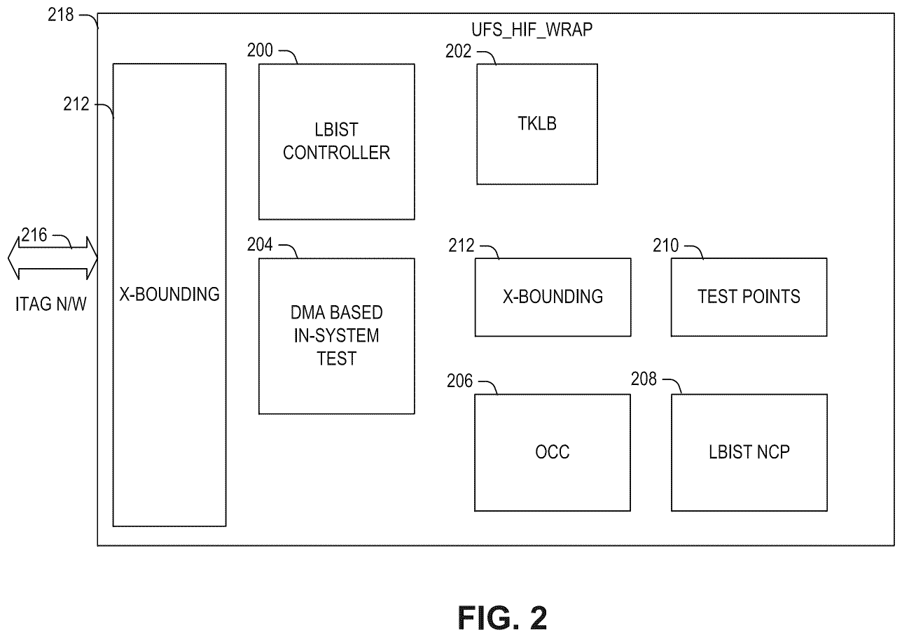

FIG. 2 illustrates generally an example of an In-System Test architecture 218 with on-demand features in the context of a Universal Flash Storage (UFS) host interface (HIF), according to some examples described herein. The example of FIG. 2 includes components of an interface wrapper or encapsulation that is configured to isolate UFS HIF logic during an LBIST process and allow implementation of safe mode and controlled testing for the memory device. The architecture includes several components that work together to enable on-demand Logic Built-In Self-Test (LBIST) functionality.

A Logic BIST controller 200 may be included to manage the overall LBIST process. The Logic BIST controller 200 may be configured for coordinating a test sequence, generating test patterns, and analyzing test results. A Test Known LBIST block or EDT block (TKLB block 202) may be implemented to provide additional test functionality. The TKLB block 202 may work in conjunction with the Logic BIST controller 200 to enhance the testing capabilities of the system. The TKLB block 202 can be configured to target specific logic structures for test as a portion of the LBIST process under the control of the LBIST controller 200.

The architecture may include a DMA based In-system Test controller 204. The DMA based In-system Test controller 204 may be configured for managing the direct memory access operations related to the LBIST process. The DMA based In-system Test controller 204 may facilitate the loading of test patterns and the retrieval of test results from memory. An On-chip Clock Controller (OCC 206) may be incorporated to manage clock signals during the LBIST process. The OCC 206 may be configured for controlling clock domains and ensuring proper synchronization during testing.

The system may include an LBIST NCP Decoder block 208. The NCP Decoder block 208 may be used to decode and process Named Capture Procedure (NCP) information, which in turn can be used to bring compatible clocks together in certain LBIST implementations to improve fault coverage and reduce pattern counts. Test Points 210 may be integrated into the architecture. The Test Points 210 may provide specific locations within the circuit where test stimuli can be applied or test responses can be observed to improve test coverage.

The architecture may incorporate one or more cross-bounding gates (X-bounding gates 212). The X-bounding gates 212 may be used to isolate indeterminate states from propagating through the system during LBIST operation. For example, the X-bounding gates 212 may be placed at the input of different functional blocks to ensure that potential sources do not corrupt IST values. The components of the LBIST architecture may be interconnected through various interfaces, including an Internal Joint Test Action Group network (IJTAG network 216). The IJTAG network 216 may facilitate communication and control between different components of the system.

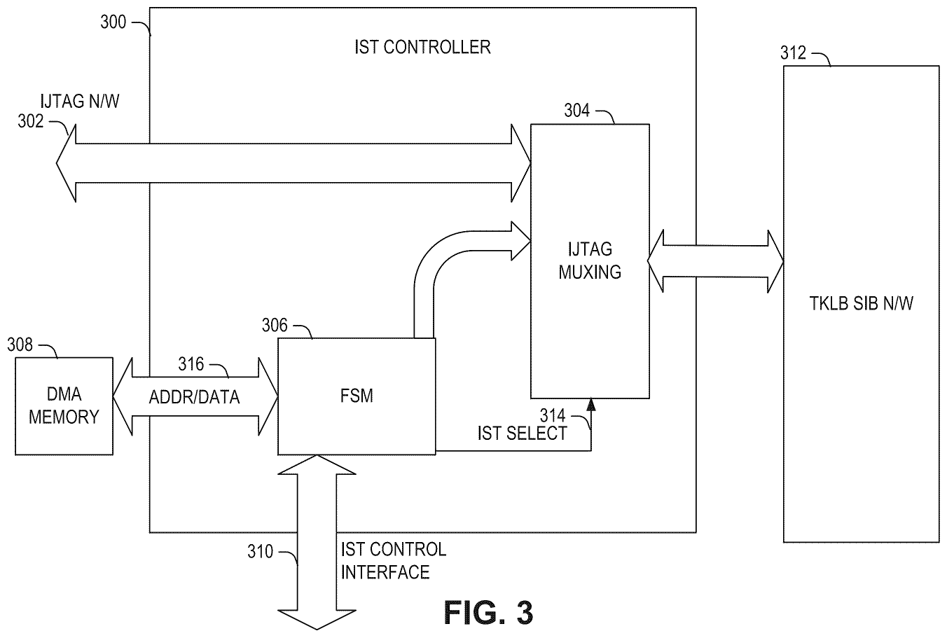

FIG. 3 illustrates an example of an In-System Test (IST) architecture with on-demand features according to some examples described herein. An IST controller 300 may be included to manage the overall LBIST process. The IST controller 300 may be configured for coordinating the test sequence, generating test patterns, and analyzing test results. The IST controller 300 may interface with other components through an Internal Joint Test Action Group network (IJTAG network 302).

The architecture may include an IJTAG MUX component 304. The IJTAG MUX component 304 may be configured for multiplexing IJTAG signals within a partition. The IJTAG MUX component 304 may be configured to allow the IST controller 300 to read from and write to any Test Data Register of the system (e.g., in LBIST, MBIST, or EDT blocks).

A finite state machine (FSM 306) may be implemented or included within the IST controller 300. The FSM 306 may control the overall LBIST process, managing the flow of test data and control signals. The FSM 306 may receive inputs such as clock, reset, and enable signals, and may generate control signals for other components within the IST controller 300.

The architecture may incorporate a DMA memory 308. This component may be used to store test patterns, configuration data, or other information required for the In-System Test operations. In some examples, the DMA memory 308 may be a random access memory (RAM) to allow for greater flexibility in test pattern generation and execution compared to traditional ROM-based solutions. An IST control interface 310 may be included for communication between the IST controller 300 and other system components, such as a host device. This interface may allow for the configuration and control of the LBIST process.

The architecture may include a TKLB SIB network component 312, which may provide additional connectivity and control options for the LBIST components. This network may use Segment Insertion Bit (SIB) interfaces to allow for flexible and scalable test configurations. For example, use of an SIB can enable selective activation or bypassing of different segments within the TKLB block, thereby providing more granular control over the testing process. An IST select signal 314 may be used to control multiplexing of IJTAG signals in the IST controller 300. In an example, the IST select signal 314 controls switching or selection between normal device operation and IST mode. In an example, the IJTAG MUX component 304 responds to the IST select signal 314 by enabling IJTAG path or the IST path to read & write from test data registers (TDRs) of LBIST, MBIST or EDT systems.

The DMA memory 308 may interface with the FSM 306 through an ADDR/DATA bus 316. This bus can be used to transfer configuration Control & Data values between the memory and the LBIST, MBIST, EDT, or OCC/Test Data Register logic.

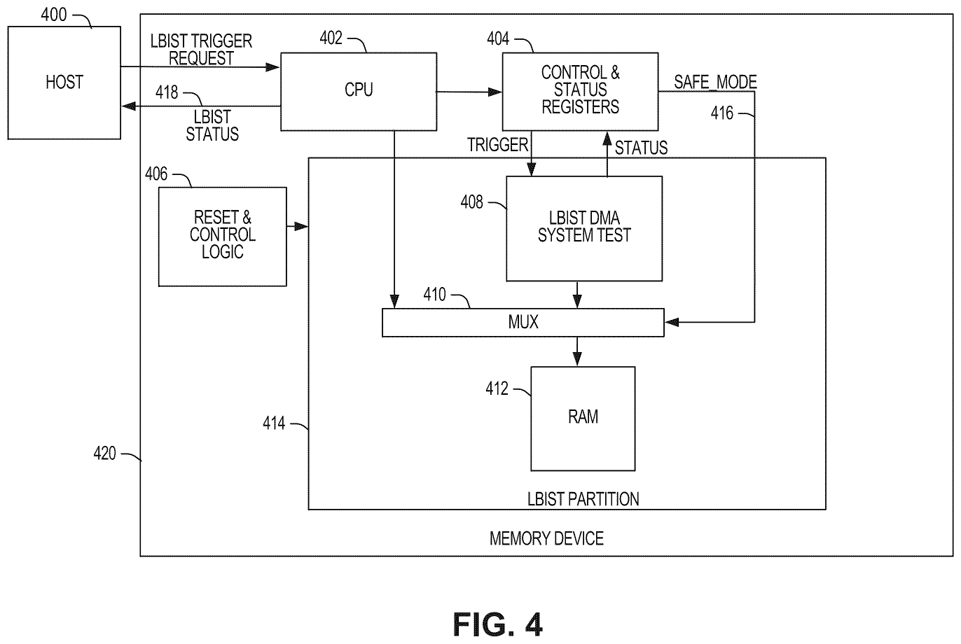

FIG. 4 illustrates an example of a memory device architecture with on-demand Logic Built-In Self-Test (LBIST) capabilities, according to some examples. Although the example of FIG. 4 generally refers to an architecture in the context of LBIST, the architecture can be similarly applied to or can use on-demand MBIST or on-demand EDT, OCC, or TDR components or processes. A host device 400 may be configured to initiate or manage a test process (e.g., LBIST, MBIST, EDT, etc.). The host device 400 may be configured to send trigger requests using vendor-specific commands (VSC) to the memory device 420. The communication between the host device 400 and the memory device 420 may occur over various interfaces, such as Compute Express Link (CXL), Peripheral Component Interconnect Express (PCIe), Universal Flash Storage (UFS), or other suitable interfaces depending on the specific implementation and requirements.

The memory device may include a central processing unit (CPU 402). The CPU 402 may be configured to process LBIST trigger requests from the host device 400 and manage an LBIST process for the memory device 420. One or more control and status registers 404 may be implemented within the memory device 420. These registers may store configuration parameters and status information related to the LBIST process. The control and status registers 404 may be accessible by the CPU 402 and one or more other components of the memory device 420.

The example memory device 420 can include a reset and control logic block 406. This component may be configured for managing reset signals and control logic for an LBIST process. The reset and control logic block 406 can be configured to provide clock and/or reset signals to other components of the memory device 420. In an example, the reset and control logic block 406 can provide signals to a LBIST partition 414.

The LBIST partition 414 can include an LBIST DMA system test block 408, a multiplexer 410, and RAM 412, among other components. The LBIST DMA system test block 408 may be configured to manage Direct Memory Access (DMA) operations related to an LBIST process. For example, this block may be configured for loading test patterns and/or retrieving test results using DMA transfers. The multiplexer 410 may be used to select between normal operation and LBIST modes, allowing for the isolation of the LBIST partition during testing.

In an example, the RAM 412 can be configured to store In-System Test-related data, such as can include one or more test patterns, configuration data, or other information for LBIST operations. In an example, the RAM 412 may store different test patterns for respective standards, such as Automotive Safety Integrity Level (ASIL) standards, thus allowing the system to implement and test for different safety requirements without hardware changes. In an example, the RAM 412 may store seed values for pseudo-random pattern generation, enabling a wide variety of test scenarios. In various examples, one or more other storage components can be used instead of the RAM 412. For example, the memory can include a storage component such as can comprise static RAM (SRAM), registers, NAND flash memory, DRAM, or other suitable storage elements. The storage component may be used to store test patterns, configuration data, or other information used in LBIST operations. The use of a programmable storage component instead of read-only memory (ROM) may allow for greater flexibility in test pattern generation and execution.

In the example of FIG. 4, the system architecture includes the LBIST partition 414. The LBIST partition 414 represents a particular portion of the memory device 420 that is subject to LBIST. This partition may contain the circuitry and logic components that are tested or evaluated during the LBIST process. A safe mode signal 416 may be implemented to enable a safe mode during LBIST operations. This signal may be used to prevent potential glitches on output ports during testing.

The memory device 420 may include an LBIST status signal path 418 to communicate the status of the LBIST process to the host device 400. This communication allows the host to monitor the progress and results of the LBIST operations. In an example, the system architecture may enable seamless integration of LBIST with other functional operations of the memory device 420. The CPU 402 may manage test initialization, which may include several operations such as ensuring no pending commands are in the UFS HIF/FE, writing LBIST code to SRAM through a secondary interface or DMA, enabling safe mode, and managing clock domains.

In an example, an on-demand LBIST procedure can include or use communication between the host device 400 and the memory device 420. This sequence may include the host sending a vendor-specific command to initiate LBIST at the memory device 420, the memory device 420 responding with one or more parameters of the LBIST operation (e.g., an expected elapsed time), execution of the LBIST operation, and finally, the memory device 420 sending LBIST status information back to the host device 400 or elsewhere.

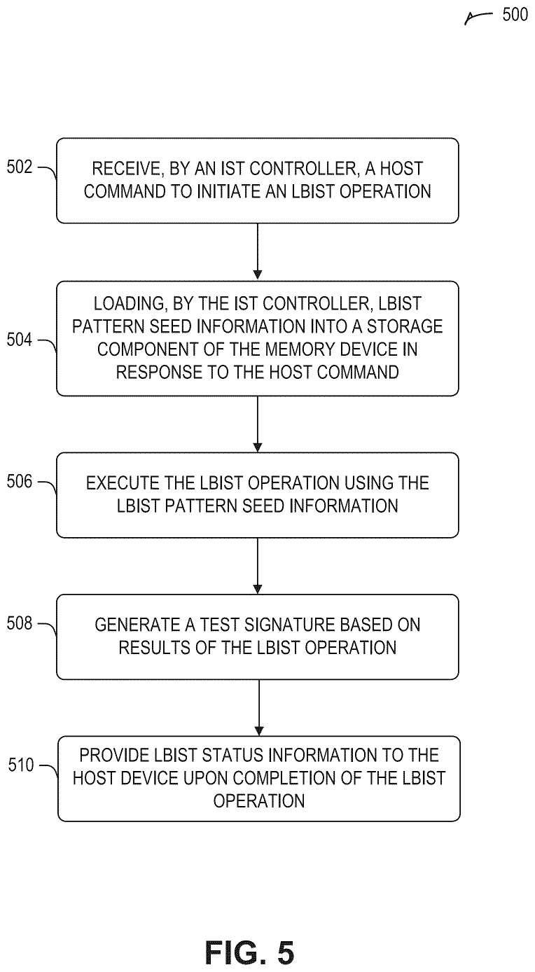

FIG. 5 illustrates generally an example method 500 for performing on-demand Logic Built-In Self-Test (LBIST) in a memory device in accordance with some examples described herein. The method may include or comprise a number of Operations or Steps. The Operations described herein are examples only, and the method may omit one or more of the listed Operations, can repeat Operations, can include other Operations, or can execute the Operations concurrently, substantially simultaneously, or in another order, as appropriate or desired.

At Operation 502, the method 500 may include receiving, by an In-System Test (IST) controller, a host command to initiate an LBIST operation. The host command may be a vendor-specific command sent from a host device to the memory device. In some examples, the host command may be received during functional operation of the memory device. The host command may include configuration parameters such as a number of test patterns to be executed, a frequency of LBIST execution, or a value of test pattern seed information.

At Operation 504, the method 500 may include loading, by the IST controller, LBIST pattern seed information into a storage component of the memory device in response to the host command. The storage component may be a random access memory (RAM) configured to store the LBIST pattern seed information. Other types of storage components can similarly be used. In some examples, the RAM may be used to store LBIST MISR information. The use of RAM instead of read-only memory (ROM) may allow for greater flexibility in test pattern generation and execution. This flexibility enables dynamic modification of test patterns without hardware changes, allowing the system to adapt to different testing requirements or standards. For example, the system can be updated to meet new safety standards or to focus on specific types of faults that may be more prevalent in certain applications.

At Operation 506, the method 500 may include executing the LBIST operation using the LBIST pattern seed information from the storage component. Operation 506 may involve several sub-operations. For example, the IST controller may stop one or more clocks input to a target functional block of the memory device, where the target functional block is indicated for the LBIST operation. A safe mode may be enabled for the target functional block to avoid output glitches. The IST controller may then generate a clock signal using an on-chip clock controller (OCC) on the memory device. The LBIST operation may then be executed according to the generated clock signal. During the LBIST execution, the IST controller may override Internal Joint Test Action Group (IJTAG) signals. The LBIST operation may involve applying test patterns to scan chains within the memory device and capturing the responses.

At Operation 508, the method 500 may include generating a test signature based on results of the LBIST operation. In an example, Operation 508 can include using a multiple input signature register (MISR) to compact one or more test responses into a signature. The test signature represents an outcome of the self-test operation and can be used to determine if the circuit has passed or failed the LBIST.

At Operation 510, the method 500 may include providing LBIST status information to the host device upon completion of the LBIST operation. The LBIST status information may be based on the test signature generated in Operation 508. The status information may include details such as whether the self-test operation passed or failed, a time duration corresponding to the self-test operation, and/or the test signature itself.

In some examples, the method 500 may include receiving an LBIST status request from the host device, and providing the LBIST status information in response to the request. The method 500 may include comparing the test signature to a reference signature and providing the LBIST status information to the host device based on this comparison. The method 500 may include additional operations not explicitly shown in FIG. 5. For example, the method may include receiving a configuration command specifying a particular test standard, such as an Automotive Safety Integrity Level (ASIL) standard, and selecting particular LBIST pattern seed information that corresponds to the specified standard. This allows the same architecture to meet different standards by adjusting test parameters. Other operations may include adjusting a frequency of LBIST execution based on the criticality of the application, modifying a value of pattern seed information to target specific types of faults, or changing a number of test patterns to be executed to balance between thorough testing and system performance.

Throughout the method 500, the IST controller may manage the overall LBIST process, coordinating with other components such as the on-chip clock controller (OCC), LBIST NCP Decoder block, and DMA-based In-System Test controller. The method 500 enables on-demand LBIST during functional operation of the memory device, supporting applications that require high reliability and continuous fault detection, such as automotive and medical equipment.

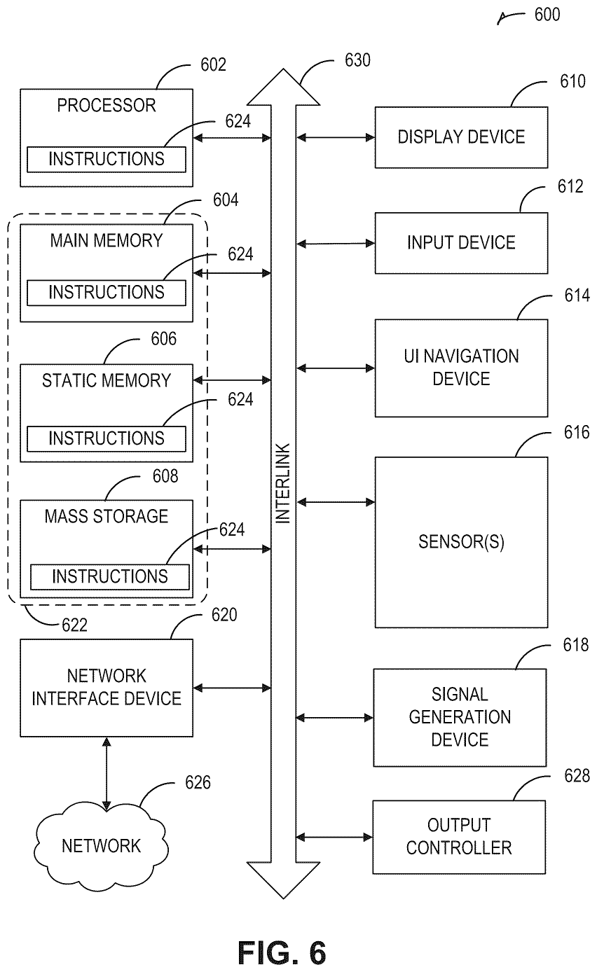

FIG. 6 is a block diagram illustrating an example of a machine 600 upon which or with which one or more embodiments can be implemented. The machine 600 can include the architecture or components discussed in the earlier figures, such as the In-System Test (IST) controller, Logic Built-In Self-Test (LBIST) components, and Direct Memory Access (DMA) based memory structures described in FIGS. 1-5. In a networked deployment, the machine 600 can operate in the capacity of a server machine, a client machine, or both in server-client network environments. In an example, the machine 600 can act as a peer machine in peer-to-peer (P2P) (or other distributed) network environment.

The machine 600 can be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, can include, or can operate by, logic or a number of components, or mechanisms. Circuit sets are a collection of circuits implemented in tangible entities that include hardware (e.g., simple circuits, gates, logic, etc.). Circuit set membership can be flexible over time and underlying hardware variability. Circuit sets include members that can, alone or in combination, perform specified operations when operating. In an example, hardware of the circuit set can be immutably designed to carry out a specific operation (e.g., hardwired). In an example, the hardware of the circuit set can include variably connected physical components (e.g., execution units, transistors, simple circuits, etc.) including a computer readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuit set in hardware via the variable connections to carry out portions of the specific operation when in operation. Accordingly, the computer readable medium is communicatively coupled to the other components of the circuit set member when the device is operating. In an example, any of the physical components can be used in more than one member of more than one circuit set. For example, under operation, execution units can be used in a first circuit of a first circuit set at one point in time and reused by a second circuit in the first circuit set, or by a third circuit in a second circuit set at a different time.

Machine 600 (e.g., a computer system) can include a hardware processor 602 (e.g., a central processing unit (CPU), a graphics processing unit (GPU), a hardware processor core, field programmable gate array (FPGA), or any combination thereof), a main memory 604 and a static memory 606, some or all of which can communicate with each other via an interlink (e.g., bus) 630. The machine 600 can further include a display unit 610, an input device 612 (e.g., an alphanumeric input device such as a keyboard), and a user interface (UI) navigation device (UI navigation device 614) (e.g., a mouse). In an example, the display unit 610, input device 612 and UI navigation device 614 can be a touch screen display. The machine 600 can additionally include a storage device 608 (e.g., drive unit), a signal generation device 618 (e.g., a speaker), a network interface device 620, and one or more sensors 616, such as a global positioning system (GPS) sensor, compass, accelerometer, or other sensor. The machine 600 can include an output controller 628, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 608 can include a machine readable medium 622 on which is stored one or more sets of data structures or one or more instructions 624 (e.g., software) embodying or used by any one or more of the techniques or functions described herein. The one or more instructions 624 can also reside, completely or at least partially, within the main memory 604, within static memory 606, or within the hardware processor 602 during execution thereof by the machine 600. In an example, one or any combination of the hardware processor 602, the main memory 604, the static memory 606, or the storage device 608 can constitute machine readable media.

While the machine readable medium 622 is illustrated as a single medium, the term “machine readable medium” can include a single medium or multiple media (e.g., a centralized or distributed database, and/or associated caches and servers) configured to store the one or more instructions 624.

The term “machine readable medium” can include any medium that is capable of storing, encoding, or carrying instructions for execution by the machine 600 and that cause the machine 600 to perform any one or more of the techniques of the present disclosure, or that is capable of storing, encoding, or carrying data structures used by or associated with such instructions. Non-limiting machine readable medium examples can include solid-state memories, and optical and magnetic media. In an example, a massed machine readable medium comprises a machine readable medium with a plurality of particles having invariant (e.g., rest) mass. Accordingly, massed machine-readable media are not transitory propagating signals. Specific examples of massed machine readable media can include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The one or more instructions 624 can further be transmitted or received over a communications network 626 using a transmission medium via the network interface device 620 utilizing any one of a number of transfer protocols (e.g., frame relay, internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards), IEEE 802.15.4 family of standards, peer-to-peer (P2P) networks, among others. In an example, the network interface device 620 can include one or more physical jacks (e.g., Ethernet, coaxial, or phone jacks) or one or more antennas to connect to the communications network 626. In an example, the network interface device 620 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 600, and includes digital or analog communications signals or other intangible medium to facilitate communication of such software.

Various aspects of the present disclosure, presented below as numerically identified Examples, can help provide a solution to the test system-related problems identified herein.

Example 1 is a memory device comprising: a storage component configured to store Logic Built-In Self-Test (LBIST) pattern seed information; an In-System Test (IST) controller coupled to the storage component and configured to: receive a command from a host device to initiate a self-test operation; in response to receiving the command, load first pattern seed information into the storage component; trigger execution of the self-test operation using the first pattern seed information from the storage component; and upon completion of the self-test operation, provide LBIST status information to the host device.

In Example 2, the subject matter of Example 1 includes a multiplexer circuit configured to receive a control signal from the IST controller and, in response, selectively route functional inputs (e.g., IJTAG signals) of the memory device or the first pattern seed information to a target functional block of the memory device.

In Example 3, the subject matter of Examples 1-2 includes the storage component comprises at least one of a random access memory (RAM), a static random access memory (SRAM), a dynamic random access memory (DRAM), a read-only memory (ROM), a memory register, and a flash memory configured to store the LBIST pattern seed information.

In Example 4, the subject matter of Example 3 includes the storage component is configured to store the LBIST status information.

In Example 5, the subject matter of Examples 1-4 includes the command is a vendor-specific command to initiate the self-test operation.

In Example 6, the subject matter of Examples 1-5 includes the memory device comprises a multiple input signature register (MISR) configured to store a test signature, wherein the test signature represents an outcome of the self-test operation.

In Example 7, the subject matter of Examples 1-6 includes the LBIST status information includes information about whether the self-test operation passed or failed, a time duration corresponding to the self-test operation, and/or a test signature that represents an outcome of the self-test operation.

In Example 8, the subject matter of Examples 1-7 includes the command comprises the first pattern seed information.

In Example 9, the subject matter of Examples 1-8 includes the IST controller is configured to enable execution of the self-test operation during functional operation of the memory device.

In Example 10, the subject matter of Examples 1-9 includes the IST controller is configured to receive the command from the host device during functional operation of the memory device.

In Example 11, the subject matter of Examples 1-10 includes an on-chip clock controller (OCC) coupled to the IST controller and configured to manage an on-chip clock domain during execution of the self-test operation.

In Example 12, the subject matter of Examples 1-11 includes the IST controller is configured to enable a safe mode for the memory device to avoid output glitches during execution of the self-test operation.

In Example 13, the subject matter of Examples 1-12 includes an Internal Joint Test Action Group (IJTAG) network that couples the IST controller and one or more other components of the memory device, and wherein the IST controller is configured to override IJTAG signals during execution of the self-test operation.

Example 14 is a system for on-demand Logic Built-In Self-Test (LBIST), the system comprising: a host device; a memory device comprising: a storage component configured to store LBIST pattern seed information; an In-System Test (IST) controller coupled to the storage component configured to: receive a command from the host device to initiate a self-test operation; in response to receiving the command, load first pattern seed information from the storage component; and trigger execution of the self-test operation using the first pattern seed information from the storage component; and upon completion of the self-test operation, provide LBIST status information to the host device; and an interface coupling the host device and the memory device.

In Example 15, the subject matter of Example 14 includes the interface coupling the host device and the memory device is at least one of a Compute Express Link (CXL) interface, Peripheral Component Interconnect Express (PCIe) interface, and a Universal Flash Storage (UFS) interface.

In Example 16, the subject matter of Examples 14-15 includes the memory device comprises a NAND flash memory device.

In Example 17, the subject matter of Examples 14-16 includes the memory device comprises a DRAM device.

Example 18 is a method for performing on-demand Logic Built-In Self-Test (LBIST) in a memory device, the method comprising: receiving, by an In-System Test (IST) controller, a host command to initiate an LBIST operation; loading, by the IST controller, LBIST pattern seed information into a storage component of the memory device in response to the host command; executing the LBIST operation using the LBIST pattern seed information from the storage component; generating a test signature based on results of the LBIST operation; providing LBIST status information to the host device upon completion of the LBIST operation, wherein the LBIST status information is based on the test signature.

In Example 19, the subject matter of Example 18 includes receiving the host command to initiate the LBIST operation includes receiving the host command during functional operation of the memory device.

In Example 20, the subject matter of Examples 18-19 includes loading the LBIST pattern seed information into the storage component includes loading the LBIST seed information into random access memory (RAM) of the memory device, and executing the LBIST operation includes using the LBIST pattern seed information from the RAM.

In Example 21, the subject matter of Examples 18-20 includes storing the test signature using the storage component.

In Example 22, the subject matter of Examples 18-21 includes executing the LBIST operation including: stopping one or more clocks input to a target functional block of the memory device, wherein the target functional block is indicated for the LBIST operation; enabling a safe mode for the target functional block; and generating a clock signal using a clock controller on the memory device; and executing the LBIST operation according to the generated the clock signal.

In Example 23, the subject matter of Examples 18-22 includes receiving an LBIST status request from the host device; wherein providing the LBIST status information is in response to the LBIST status request.

In Example 24, the subject matter of Examples 18-23 includes comparing the test signature to a reference signature and providing the LBIST status information to the host device based on the comparison.

In Example 25, the subject matter of Examples 18-24 includes, receiving, by the IST controller, a configuration command specifying an Automotive Safety Integrity Level (ASIL) requirement; and selecting, based on the specified ASIL requirement, particular LBIST pattern seed information that corresponds to a particular ASIL level; wherein loading the LBIST pattern seed information into the storage component of the memory device includes loading the particular LBIST pattern seed information; and wherein executing the LBIST operation includes using the particular LBIST pattern seed information.

In Example 26, the subject matter of Example 25 includes receiving the configuration command, including receiving a command to adjust one or more of a number of test patterns to be executed, a frequency of the LBIST execution, or a value of the pattern seed information.

Example 27 is at least one machine-readable medium including instructions that, when executed by processing circuitry, cause the processing circuitry to perform operations to implement of any of Examples 1-26.

Example 28 is an apparatus comprising means to implement of any of Examples 1-26.

Each of these non-limiting Examples can stand on its own, or can be combined in various permutations or combinations with one or more of the other Examples or features discussed elsewhere herein.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the embodiments should be determined with reference to the appended claims, along with the full scope of equivalents to which such claims are entitled.

What is claimed is:

1. A memory device comprising:
a storage component configured to store Logic Built-In Self-Test (LBIST) pattern seed information;
an In-System Test (IST) controller coupled to the storage component and configured to:
receive a command from a host device to initiate a self-test operation;
in response to receiving the command, load first pattern seed information into the storage component;
trigger execution of the self-test operation using the first pattern seed information from the storage component; and
upon completion of the self-test operation, provide LBIST status information to the host device.

2. The memory device of claim 1, comprising a multiplexer circuit configured to receive a control signal from the IST controller and, in response, selectively route functional inputs (e.g., IJTAG signals) of the memory device or the first pattern seed information to a target functional block of the memory device.

3. The memory device of claim 1, wherein the storage component comprises at least one of a random access memory (RAM), a static random access memory (SRAM), a dynamic random access memory (DRAM), a read-only memory (ROM), a memory register, and a flash memory configured to store the LBIST pattern seed information, and wherein the storage component is configured to store the LBIST status information.

4. The memory device of claim 1, wherein the command is a vendor-specific command to initiate the self-test operation.

5. The memory device of claim 1, wherein the memory device comprises a multiple input signature register (MISR) configured to store a test signature, wherein the test signature represents an outcome of the self-test operation.

6. The memory device of claim 1, wherein the LBIST status information includes information about whether the self-test operation passed or failed, a time duration corresponding to the self-test operation, and/or a test signature that represents an outcome of the self-test operation.

7. The memory device of claim 1, wherein the command comprises the first pattern seed information.

8. The memory device of claim 1, wherein the IST controller is configured to enable execution of the self-test operation during functional operation of the memory device.

9. The memory device of claim 1, wherein the IST controller is configured to receive the command from the host device during functional operation of the memory device.

10. The memory device of claim 1, comprising an on-chip clock controller (OCC) coupled to the IST controller and configured to manage an on-chip clock domain during execution of the self-test operation.

11. The memory device of claim 1, wherein the IST controller is configured to enable a safe mode for the memory device to avoid output glitches during execution of the self-test operation.

12. The memory device of claim 1, comprising an Internal Joint Test Action Group (IJTAG) network that couples the IST controller and one or more other components of the memory device, and wherein the IST controller is configured to override IJTAG signals during execution of the self-test operation.

13. A system for on-demand Logic Built-In Self-Test (LBIST), the system comprising:
a host device;
a memory device comprising:
a storage component configured to store LBIST pattern seed information;
an In-System Test (IST) controller coupled to the storage component configured to:
receive a command from the host device to initiate a self-test operation;
in response to receiving the command, load first pattern seed information from the storage component; and
trigger execution of the self-test operation using the first pattern seed information from the storage component; and
upon completion of the self-test operation, provide LBIST status information to the host device; and
an interface coupling the host device and the memory device.

14. The system of claim 13, wherein the interface coupling the host device and the memory device is at least one of a Compute Express Link (CXL) interface, Peripheral Component Interconnect Express (PCIe) interface, and a Universal Flash Storage (UFS) interface.

15. The system of claim 13, wherein the memory device comprises a NAND flash memory device or a DRAM device.

16. A method for performing on-demand Logic Built-In Self-Test (LBIST) in a memory device, the method comprising:
receiving, by an In-System Test (IST) controller, a host command to initiate an LBIST operation during functional operation of the memory device;
loading, by the IST controller, LBIST pattern seed information into a storage component of the memory device in response to the host command;
executing the LBIST operation using the LBIST pattern seed information from the storage component;
generating a test signature based on results of the LBIST operation;
providing LBIST status information to the host device upon completion of the LBIST operation, wherein the LBIST status information is based on the test signature.

17. The method of claim 16, wherein loading the LBIST pattern seed information into the storage component includes loading the LBIST seed information into random access memory (RAM) of the memory device, and wherein executing the LBIST operation includes using the LBIST pattern seed information from the RAM.

18. The method of claim 16, wherein executing the LBIST operation includes:
stopping one or more clocks input to a target functional block of the memory device, wherein the target functional block is indicated for the LBIST operation; enabling a safe mode for the target functional block; and
generating a clock signal using a clock controller on the memory device; and executing the LBIST operation according to the generated the clock signal.

19. The method of claim 16, comprising comparing the test signature to a reference signature and providing the LBIST status information to the host device based on the comparison.

20. The method of claim 16, comprising:
receiving, by the IST controller, a configuration command specifying an Automotive Safety Integrity Level (ASIL) requirement; and
selecting, based on the specified ASIL requirement, particular LBIST pattern seed information that corresponds to a particular ASIL level;
wherein loading the LBIST pattern seed information into the storage component of the memory device includes loading the particular LBIST pattern seed information;
wherein executing the LBIST operation includes using the particular LBIST pattern seed information; and
wherein receiving the configuration command includes receiving a command to adjust one or more of a number of test patterns to be executed, a frequency of the LBIST execution, or a value of the pattern seed information.
